(19) United States
(12) Patent Application Publication
(10) Pub. No.: US 2026/0096461 A1
(43) Pub. Date: Apr. 2, 2026

(54) ELECTRONIC CHIP, HAVING A LOCALLY PATTERNED PERIPHERAL AREA, INTENDED TO BE GLUED TO SUBSTRATE

(71) Applicant: STMicroelectronics International N.V., Geneva (CH)

(72) Inventors: Lou ROULON, Grenoble (FR); Boris BOUILLARD, Cognin (FR)

(73) Assignee: STMicroelectronics International N.V., Geneva (CH)

(21) Appl. No.: 19/346,926

(22) Filed: Oct. 1, 2025

(30) Foreign Application Priority Data
Oct. 1, 2024 (FR) FR2410574

(51) Int. Cl. H01L 23/00

(52) U.S. Cl. CPC H10W 72/30; H10W 72/387; H10W 90/734

(57) ABSTRACT

An electronic chip includes a first main surface, intended to be glued to a substrate, a second main surface, and lateral surfaces. The second main surface includes a central area and a locally patterned peripheral area. The locally patterned peripheral area successively forms, from the central area, a first portion having a first thickness and a second portion having a second thickness. The first thickness is smaller than the thickness of the central area. The second thickness is greater than the first thickness and smaller than the thickness of the central area.

### PRIORITY CLAIM

This application claims the priority benefit of French Application for Patent No. FR2410574, filed on Oct. 1, 2024, the content of which is hereby incorporated by reference in its entirety to the maximum extent allowable by law.

### TECHNICAL FIELD

The present disclosure generally concerns the field of electronic (integrated circuit) chips, and more particularly, electronic chips to be glued on a support.

### BACKGROUND

Electronic chips are sometimes assembled on supports by means of a glue layer. However, the glue often runs up the sides of the chip, or even covers part of the front surface of the chip, which may decrease its performance, contaminate the connection pads on the front surface, and/or contaminate the tools used to handle it (for example, a pick and place tool). To avoid these disadvantages, the glue should not cover more than 80% of the chip thickness.

Now, glue management during the bonding of the chip is difficult to control due to different factors: the nature of the glue, the type of chip and of dicing performed, the thickness of the chip, the substrate design.

There exists a need to at least partly improve certain aspects of known methods of gluing electronic chips to external elements, such as substrates.

### SUMMARY

Embodiments herein comprise: an electronic chip comprising a first main surface, intended to be glued to a substrate, a second main surface, lateral surfaces, the second main surface comprising a central area and a peripheral area, the peripheral area being locally patterned at a first edge, so as to successively form, from the central area, a first portion having a first thickness, a second portion having a second thickness, the first thickness being smaller than the thickness of the central area, the second thickness being greater than the first thickness and smaller than the thickness of the central area.

According to a specific embodiment, the chip further comprises a third portion having a third thickness, the third thickness being smaller than the second thickness, the second portion being positioned between the first portion and the third portion.

According to a specific embodiment, the first thickness is smaller than the third thickness.

According to a specific embodiment, the peripheral area is patterned at a second edge, where the patterning at the first edge and the patterning at the second edge may be identical or different, the second edge preferably being opposite to the first edge.

According to a specific embodiment, the peripheral area is patterned at the four edges of the chip, the patterning of the four edges being preferably identical.

According to a specific embodiment, the second thickness amounts to from 40 to 90% of the thickness of the central area, preferably from 50 to 80% of the thickness of the central area.

According to a specific embodiment, the central area has a thickness in the range from 50 and 250 μm, preferably from 50 to 150 μm, even more preferably from 50 to 80 μm.

According to a specific embodiment, the thickness difference between the first portion and the second portion is at least 2 μm and/or the width of the first portion is at least 5 μm to be able to contain a solvent before its evaporation.

Embodiments herein further comprise an assembly method comprising a step during which a chip such as previously defined is assembled to an external element by means of a glue layer, arranged between the chip and the external element.

Embodiments herein further comprise an assembly comprising a chip such as previously defined and an external element, such as a substrate, a glue layer being arranged between the chip and the external element.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 schematically shows, in side and cross-section view, a portion of an electronic chip according to a specific embodiment;

FIG. 2 schematically shows, in three-dimensions, an electronic chip according to another specific embodiment;

FIG. 3 schematically shows, in side and cross-section view, a portion of an electronic chip according to another specific embodiment;

FIG. 4 schematically shows, in side and cross-section view, a portion of an electronic chip according to another specific embodiment;

FIG. 5 schematically shows, in side and cross-section view, a portion of an assembly comprising an electronic chip and a substrate, assembled by means of a glue layer, according to another specific embodiment;

FIG. 6 is an image obtained with an optical microscope of a portion of an assembly comprising an electronic chip and a substrate, assembled by means of a glue layer, according to another specific embodiment;

FIG. 7 is an image obtained with an optical microscope of a portion of an assembly comprising an electronic chip and a substrate, assembled by means of a glue layer, according to a comparative example.

### DETAILED DESCRIPTION

The various elements are not necessarily shown at a uniform scale, to make the drawings more readable.

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail.

Also for clarity, the electronic components formed inside or on top of the substrate are not shown.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10%, preferably of plus or minus 5%.

Unless specified otherwise, by in the range from X to Y, there is meant that terminals X and Y are included in the range.

Electronic components apply in a wide range of industrial fields, and in particular in the field of microelectromechanical systems (MEMS), of power amplifiers, of proximity sensors, or also of optical modules.

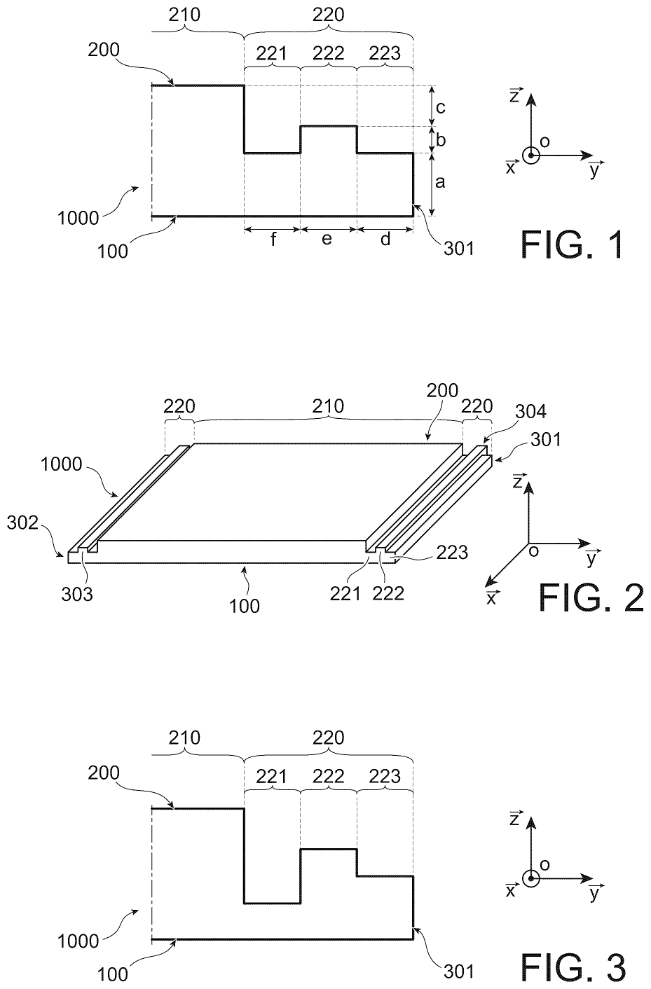

Electronic (integrated circuit) chip 1000 will be described in further detail with reference to FIGS. 1 to 5.

Chip 1000 comprises a first main surface 100 and a second main surface 200.

The first main surface 100 is the rear surface. It is the surface intended to be glued to an external element.

The second main surface 200 is the front surface. It is the active side. Chip 1000 may comprise one or a plurality of discrete components. The discrete component(s) are, for example, selected from among transistors, diodes, thyristors, triacs, filters, etc. The chip may comprise one or a plurality of integrated electronic circuits. The chip enables to implement different electronic functions and may have various applications. As an illustration, the chip may be a MEMS, a power amplifier, an optical sensor, or a microcontroller. The second surface 200 also comprises electrical connection pads (not shown).

The main surfaces 100, 200 are, for example, rectangular.

Chip 1000 further comprises side walls, generally four side walls 301, 302, 303, 304 resulting from the cutting of a semiconductor wafer. The side walls couple the first main surface 100 to the second main surface 200.

The second main surface 200 comprises a central area 210 and a peripheral area 220. Peripheral area 220 surrounds central area 210.

The active area of chip 1000 and the connection pads are located in central area 210.

Central area 210 has a thickness corresponding to the thickness of the chip substrate.

Peripheral area 220 is positioned on the edges of the second main surface 200. In the case of a rectangular-shaped main surface, the peripheral area is located on the four edges of the main surface.

Peripheral area 220 comprises no components: it is a sacrificial area.

The peripheral area is locally patterned. Its local patterning does not prevent the operation of the chip.

The patterning enables to create multiple interfaces on one or a plurality of edges of chip 1000. During the bonding of chip 1000 to an external element 300 via its rear surface 100, these interfaces will slow down (impede) or even stop the glue and prevent the glue from completely covering the side walls of chip 1000.

At least one of the edges of peripheral area 220 is patterned. Preferably, two of the edges of the peripheral area are patterned, the patterned edges being opposite to each other. All the edges of the peripheral area may be patterned. In other words, the patterning is performed all around the second surface 200.

According to an alternative embodiment, for example shown in FIGS. 1 to 3 and 5, the patterning of the edge(s) of peripheral area 220 may comprise, from central area 210 to the edge of chip 1000: a first portion 221 having a first thickness, a second portion 222 having a second thickness, a third portion 223 having a third thickness.

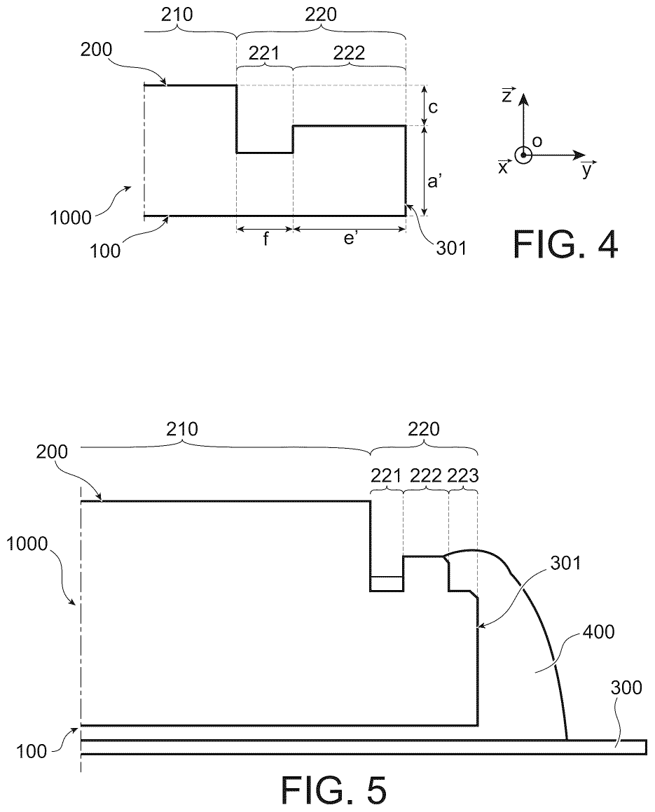

According to another embodiment, for example shown in FIG. 4, the patterning of the edge(s) of the peripheral area comprises from central area 210 towards the edge of chip 1000: a first portion 221 having a first thickness, a second portion 222 having a second thickness.

By thickness, there is meant the dimension along the z axis.

The width of a given portion is defined along the y axis.

According to these alternative embodiments, either the second portion 222 or the third portion 223 forms a shoulder on one of the lateral surfaces 301, 302, 303, 304. The shoulder enables to slow down the progress of glue 400.

The second portion 222 enables to stop the progress of glue 400. The second portion has a width, for example, of more than 2 μm. The second thickness amounts, for example, to at least 40% of the thickness of central area 210, or even at least 50% of the thickness of central area 210. The second thickness amounts, for example, to at most 90% of the thickness of central area 210, or even at most 80% of the thickness of central area 210.

The first portion 221 has a thickness less than the thickness of central portion 210 and less than the thickness of the second portion 222. The first portion 221 is formed between central area 210 and the second portion 222. The first portion 221 forms a groove in peripheral area 220. During the assembly with an external element 300, for example a substrate, by means of a glue layer 400, this groove will enable to contain the solvent of the glue. It also prevents the progress of the glue towards central area 210, since the thickness of the first portion 221 is lower than the thickness of central area 210.

The thickness difference between the first portion 221 and the second portion 222 is, for example, at least 2 μm. The width of the first portion is, for example, at least 5 μm. The cavity formed enables to contain the solvent of the glue before its evaporation.

With such chips, glue 400 does not covers more than 80% of the chip thickness. It covers, for example, in the range from 20% and 80% of the thickness of chip 1000.

As a non-limiting illustration, the patterning of a chip such as shown in FIG. 1 and having a thickness greater than 50 μm, for example 70 μm or 80 μm, may have the characteristics given in the following Table 1:

| Thickness (μm) | | | Width (μm) | | |
|---|---|---|---|---|---|
| a | b | c | d | e | f |
| >50 | >20 | >5 | >1 | >2 | >5 |

As a non-limiting illustration, the patterning of a chip such as shown in FIG. 4 and having a thickness greater than 50 μm, for example 70 μm or 80 μm, may have the characteristics given in the following Table 2:

| | |
|---|---|
| Thickness (μm) | Width (μm) |

| a′ | c | e′ | f |
|---|---|---|---|
| >20 | >5 | >2 | >5 |

One or a plurality of edges of the portions 221, 222, 223 of peripheral area 220 may be beveled, as for example shown in FIG. 5. In other words, they may exhibit a bevel or chamfer.

Such chips 1000 may be formed by a method implementing one or a plurality of laser cutting and/or mechanical cutting and/or plasma etching steps.

Chip 1000 may be assembled to an external element 300 by means of a glue layer 400. Glue layer 400 is arranged between the first surface 100 of the chip and external element 300.

Due to the patterning of the periphery 220 of the chip, the progress of glue 400 is stopped at the second portion 222. Glue layer 400 does not run up to more than 80% of the chip thickness (that is, of the thickness of the central area), even for chips having low thicknesses (typically less than 100 μm thick).

With such a chip, it is possible not only to use a wide range of equipment, and in particular less expensive equipment, but also to have a wider choice for the glue.

The number of control steps for the obtained assemblies is thus decreased. The efficiency is increased.

Glues that can be used in the assembly method are, for example, epoxy-type or silicone-type glues. The glues may contain particles, for example insulating particles or conductive particles. The insulating particles may be alumina or silica particles. The conductive particles may be silver particles and/or copper particles.

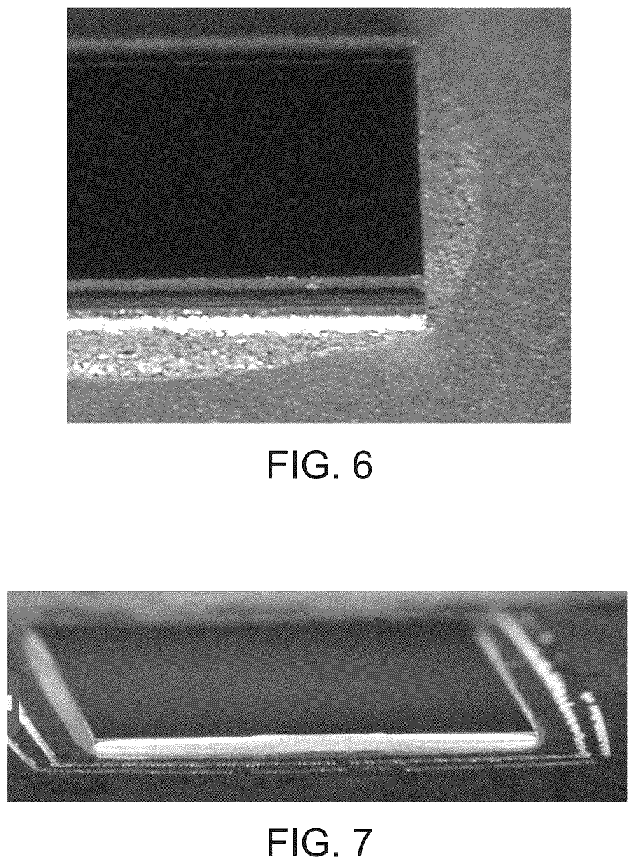

In testing, 70 μm thick chips have been patterned as previously described and bonded to a substrate. The glue runs up the side walls of the chip, but covers less than 80% of the thickness of the side wall (FIG. 6).

If the chip is non-patterned, the glue may run up until it completely covers the side walls of the chip, even for chips having very large thicknesses, typically more than 200 μm thick, for example 230 μm (FIG. 7).

Such chips 1000 apply in a wide range of industrial fields, and in particular in the automotive sector, for personal electronics, especially in the field of communications equipment, computers, and peripherals. They may also be used in new GaN technologies, in power packages, in electronic amplifiers.

They may, for example, be 5G connection devices or more generally connected devices.

They may also be advanced driver-assistance systems (ADAS).

Electronic chip 1000 may be used in a smartphone or for the Internet of Things (IoT). The device is for example connected via 5G, WIFI, or Ultra-Wide Band (UWB).

Electronic chip 1000 may also be of interest in other fields, such as for example for the industrial field, particularly for green energies.

Such applications are given as an illustration and are not limiting.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

1. An electronic chip, comprising:
a first main surface configured to be glued to a substrate;
a second main surface;
lateral surfaces;
wherein the second main surface comprises a central area and a peripheral area;
wherein the peripheral area has a local pattern at a first edge which successively forms, from the central area:
a first portion of the peripheral area having a first thickness;
a second portion of the peripheral area having a second thickness; and
a third portion of the peripheral area having a third thickness;
wherein the second portion is positioned between the first and third portions;
wherein the first thickness is less than a thickness of the central area;
wherein the second thickness is greater than the first thickness and less than the thickness of the central area; and
wherein the third thickness is less than the second thickness.

2. The chip according to claim 1, wherein each of the first portion, second portion and third portion comprises a surface defining the first thickness, second thickness and third thickness, respectively, that extends parallel to the first and second main surfaces.

3. The chip according to claim 1, wherein the first thickness is less than the third thickness.

4. The chip according to claim 1, wherein the peripheral area is patterned at a second edge, where patterning at the first edge and patterning at the second edge are identical, the second edge preferably being opposite to the first edge.

5. The chip according to claim 1, wherein the peripheral area is patterned at a second edge, where patterning at the first edge and patterning at the second edge are different, the second edge preferably being opposite to the first edge.

6. The chip according to claim 1, wherein the peripheral area is patterned at all edges of the chip, the patterning of all edges being identical.

7. The chip according to claim 1, wherein the second thickness amounts to from 40% to 90% of the thickness of the central area.

8. The chip according to claim 1, wherein the second thickness amounts to from 50% to 80% of the thickness of the central area.

9. The chip according to claim 1, wherein the central area has a thickness in a range from 50 to 250 μm.

10. The chip according to claim 1, wherein the central area has a thickness in a range from 50 to 150 μm.

11. The chip according to claim 1, wherein the central area has a thickness in a range from 50 to 80 μm.

12. The chip according to claim 1, wherein a thickness difference between the first portion and the second portion is at least 2 μm.

13. The chip according to claim 1, wherein a width of the first portion is at least 5 μm.

14. An assembly method, comprising a step during which the chip of claim 1 is assembled to an external element by a glue layer that is arranged between the first main surface of the chip and the external element.

15. An assembly, comprising:
the chip of claim 1; and
an external element forming a substrate; and
a glue layer arranged between the first main surface of the chip and the external element.
